(19) United States
(12) Patent Application Publication
(10) Pub. No.: US 2025/0155501 A1
(43) Pub. Date: May 15, 2025

(54) CHIP AND CHIP TESTING METHOD

(71) Applicant: REALTEK SEMICONDUCTOR CORPORATION, Hsinchu (TW)

(72) Inventors: Chang-Hsien Tai, Hsinchu (TW); Ren-Li Yang, Hsinchu (TW)

(21) Appl. No.: 18/930,248

(22) Filed: Oct. 29, 2024

(30) Foreign Application Priority Data
Nov. 9, 2023 (TW) 112143270

(51) Int. Cl. G01R 31/317; G01R 31/28

(52) U.S. Cl. CPC G01R 31/31727; G01R 31/2836

(57) ABSTRACT

A chip testing method includes the following operations: during a chip probe testing, executing, by a processor circuit in a chip, a code to generate a first test signal; and during the chip probe testing, utilizing the first test signal to perform a transition delay fault test on a first circuit in the chip.

### BACKGROUND OF THE INVENTION

### 1. Field of the Invention

The present disclosure relates to a chip testing method, especially to a chip testing method and a chip that may perform a transition delay fault test on asynchronous circuit(s) in the chip during a chip probe testing.

### 2. Description of Related Art

In order to ensure the yield of integrated circuits, various circuit tests are required at different manufacturing stages of integrated circuits. In existing approaches, additional test patterns need to be added to a functional test to test asynchronous circuits. As a result, the complexity of the tests is increased, and more test time is required. Moreover, functional tests are performed after the chip is packaged, which is a later stage in circuit test. If faults in asynchronous circuits are detected at this stage, unnecessary costs will be increased.

### SUMMARY OF THE INVENTION

In some aspects of the present disclosure, one of the objectives of the present disclosure is, but not limited to, to provide a chip testing method and a chip that may perform a transition delay fault (TDF) test on asynchronous circuit(s) in the chip during a chip probe testing, so as to improve the deficiencies of the prior art.

In some aspects of the present disclosure, a chip testing method includes the following operations: during a chip probe testing, executing, by a processor circuit in a chip, a code to generate a first test signal; and during the chip probe testing, utilizing the first test signal to perform a transition delay fault test on a first circuit in the chip.

In some aspects of the present disclosure, a chip includes a memory circuit, a processor circuit, and a first circuit. The memory circuit is configured to store a code. The processor circuit is configured to execute the code during a chip probe testing to generate a first test signal. The first circuit is coupled to the processor circuit via a bus circuit and is configured to perform a transition delay fault test in response to the first test signal during the chip probe testing.

These and other objectives of the present disclosure will no doubt become obvious to those of ordinary skill in the art after reading the following detailed description of the preferred embodiments that are illustrated in the various figures and drawings.

### BRIEF DESCRIPTION OF THE DRAWINGS

FIG. 1 illustrates a schematic diagram of a chip according to some embodiments of the present disclosure.

FIG. 2 illustrates a flowchart of a multi-stage test performed on the chip according to some embodiments of the present disclosure.

FIG. 3 illustrates a flowchart of a chip testing method according to some embodiments of the present disclosure.

### DETAILED DESCRIPTION OF THE PREFERRED EMBODIMENTS

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

In this document, the term “coupled” may also be termed as “electrically coupled,” and the term “connected” may be termed as “electrically connected.” “Coupled” and “connected” may mean “directly coupled” and “directly connected” respectively, or “indirectly coupled” and “indirectly connected” respectively. “Coupled” and “connected” may also be used to indicate that two or more elements cooperate or interact with each other. In this document, the term “circuitry” may indicate a system implemented with at least one circuit, and the term “circuit” may indicate an object, which is formed with one or more transistors and/or one or more active/passive elements based on a specific arrangement, for processing signals.

As used herein, the term “and/or” includes any and all combinations of one or more of the associated listed items. Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. For ease of understanding, similar/identical elements in various figures are designated with the same reference number.

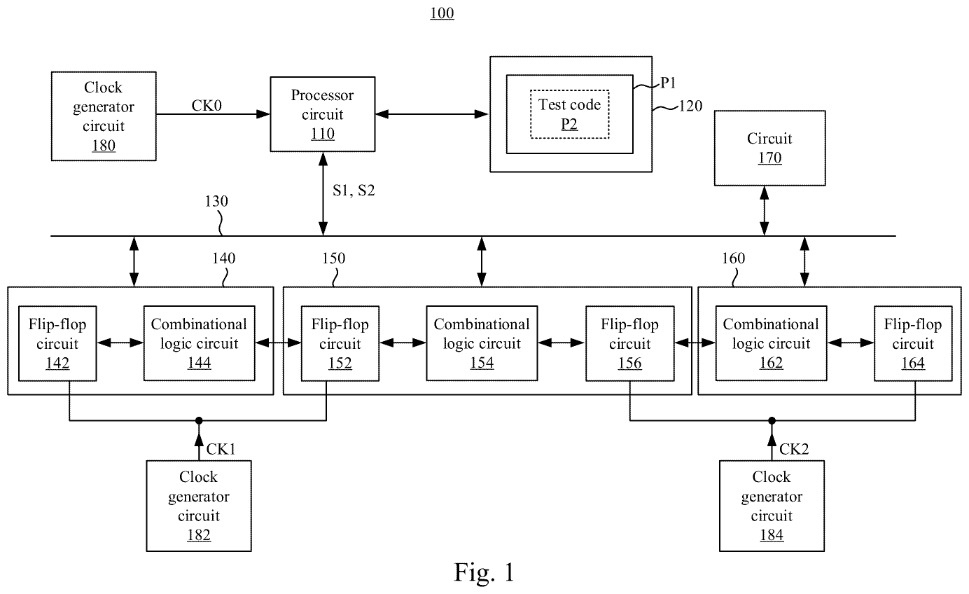

FIG. 1 illustrates a schematic diagram of a chip 100 according to some embodiments of the present disclosure. The chip 100 includes a processor circuit 110, a memory circuit 120, a bus circuit 130, a circuit 140, an asynchronous circuit 150, a circuit 160, a circuit 170, and clock generator circuits 180, 182, and 184.

The memory circuit 120 is coupled to the processor circuit 110 and is configured to store a code P1. In some embodiments, the code P1 may be a program code executed by the processor circuit 110 when operating in a normal mode. For example, the code P1 may include, but is not limited to, a program code executed by the processor circuit 110 during a boot process. In some embodiments, the program code may be, but is not limited to, a bootloader that initializes and configures circuits (e.g., the circuit 140, the asynchronous circuit 150, the circuit 160, and the circuit 170) in the chip 100, thereby enabling these circuits to interact with each other. In some embodiments, the memory circuit 120 may be, but is not limited to, a read-only memory (ROM) circuit.

The processor circuit 110 may be coupled to the circuit 140, the asynchronous circuit 150, the circuit 160, and the circuit 170 via the bus circuit 130. In some embodiments, the bus circuit 130 may include, but is not limited to, an internal data bus, a memory bus, a system bus, and/or an inter-integrated circuit bus, which may connect the aforementioned circuits, enabling these circuits to exchange electronic signals, data, and/or instructions with each other.

In some embodiments, the processor circuit 110 may be, but is not limited to, a signal processing circuit with computing capabilities. For example, the processor circuit 110 may be, but is not limited to, a central processing unit, a microcontroller, or the like. In different embodiments, during a chip probe testing, the processor circuit 110 may execute the code P1 to generate a corresponding test signal (e.g., a test signal (e.g., test sequence) S1 or a test signal (e.g., test sequence) S2) to perform circuit test on at least one of the circuit 140, the asynchronous circuit 150, the circuit 160, and/or the circuit 170. In some embodiments, the aforementioned circuit test may be, but is not limited to, a transition delay fault test. The transition delay fault test may be employed to detect and evaluate signal transmission delays in the aforementioned circuits. If the transition delay of a signal at a specific node (which may be, for example but not limited to, an input/output node) in the aforementioned circuits exceeds a specific period, it may cause performance degradation or functional abnormalities of the circuit. During the chip probe testing, the processor circuit 110 may execute the code P1 to trigger signal transmission or data access behaviors among at least one of the aforementioned circuits, in order to perform the transition delay fault test on these circuits. In some embodiments, the circuit 140, the asynchronous circuit 150, the circuit 160, and/or the circuit 170 may return the test results to the processor circuit 110 and/or external tools, in order to determine whether at least one of these circuits has a transition delay fault and identify a location of the node that causes the transition delay fault.

In some embodiments, the circuit 140, the asynchronous circuit 150, the circuit 160, and the circuit 170 are circuits under test in the chip 100. In some embodiments, each of the circuit 140, the asynchronous circuit 150, and the circuit 160 may perform the transition delay fault test during the chip probe testing in response to the test signal S1. In some embodiments, the circuit 170 may perform the transition delay fault test during the chip probe testing in response to the test signal S2.

In some embodiments, the asynchronous circuit 150 is coupled between the circuit 140 and the circuit 160, and the circuit 140 and the circuit 160 may access and/or exchange signals with each other via the asynchronous circuit 150. In some embodiments, the circuit 140 is configured to operate according to a clock signal (e.g., clock sequence) CK1 (i.e., operating in a first clock domain defined by the clock signal CK1), the circuit 160 is configured to operate according to a clock signal (e.g., clock sequence) CK2 (i.e., operating in a second clock domain defined by the clock signal CK2), and the asynchronous circuit 150 is configured to operate according to the clock signal CK1 and the clock signal CK2 (for example, part of the circuits in the asynchronous circuit 150 operate in the first clock domain, and another part of the circuits in the asynchronous circuit 150 operate in the second clock domain). In some embodiments, the clock signal CK1 and the clock signal CK2 are asynchronous. In some embodiments, the clock signal CK1 and the clock signal CK2 come from different clock sources. In some embodiments, a frequency of one of the clock signal CK1 and the clock signal CK2 is not an integer of a frequency of another one of the clock signal CK1 and the clock signal CK2. In some embodiments, if the clock signal CK1 and the clock signal CK2 meet at least one of the aforementioned conditions, it indicates that the clock signal CK1 and the clock signal CK2 are asynchronous signals.

For example, the circuit 140 may include, but is not limited to, a flip-flop circuit 142 and a combinational logic circuit 144, which may operate as a fan-in cone circuit. The flip-flop circuit 142 may be triggered by the clock signal CK1 to transmit the test signal S1 to the combinational logic circuit 144. The combinational logic circuit 144 may access the circuit 160 via the asynchronous circuit 150 according to the test signal S1 (for example, to transmit a corresponding signal to the circuit 160 or to receive a corresponding signal from the circuit 160). The asynchronous circuit 150 may include, but is not limited to, a flip-flop circuit 152, a combinational logic circuit 154, and a flip-flop circuit 156. The flip-flop circuit 152 may be triggered by the clock signal CK1 to transmit signals from the combinational logic circuit 144 to the combinational logic circuit 154. The combinational logic circuit 154 may process the signals and transmit the corresponding signals to the flip-flop circuit 156. The flip-flop circuit 156 may be triggered by the clock signal CK2 to transmit the signals generated by the combinational logic circuit 154 to the circuit 160. The circuit 160 may include, but is not limited to, a combinational logic circuit 162 and a flip-flop circuit 164, which may operate as a fan-out cone circuit. The combinational logic circuit 162 may operate according to the signals output by the flip-flop circuit 156 to generate corresponding signals for the flip-flop circuit 164. The flip-flop circuit 164 may be triggered by the clock signal CK2 to output the signals generated by the combinational logic circuit 162. During the aforementioned operation process, the processor circuit 110 and/or external tools may obtain signals at internal nodes (especially nodes that receive and/or output signals) of the circuit 140, the asynchronous circuit 150, and the circuit 160, in order to determine whether a transition delay fault is detected based on these signals.

The aforementioned configurations of the circuit 140, the asynchronous circuit 150, and the circuit 160 are given for illustrative purposes, and the present disclosure is not limited thereto. It is understood that the circuit 140, the asynchronous circuit 150, and the circuit 160 may be various types of digital circuits. The aforementioned descriptions only utilize the circuit 140 accessing the circuit 160 via the asynchronous circuit 150 as an example, and the present disclosure is not limited thereto. It is understood that, in different embodiments, the circuit 160 may also access the circuit 140 via the asynchronous circuit 150, that is, the circuit 140 and the circuit 160 may transmit bidirectionally via the asynchronous circuit 150, and the circuit 160 may also access the circuit 140 via the asynchronous circuit 150 in response to the test signal S1.

In some embodiments, the circuit 170 may be independent of the circuit 140, the asynchronous circuit 150, and the circuit 160. In other words, at least one circuit among the circuit 140, the asynchronous circuit 150, and the circuit 160 does not access the circuit 170, and vice versa. The circuit 170 is coupled to the processor circuit 110 via the bus circuit 130. In some embodiments, the circuit 170 may include, but is not limited to, a memory circuit (e.g., a static random-access memory circuit). In some embodiments, the processor circuit 110 may directly access the data of the memory circuit.

In some embodiments, the code P1 further includes a test code P2, which may be employed to perform tests (which may be, but not limited to, transition delay fault test) on circuits directly associated with the processor circuit 110 (such as the circuit 170). During the chip probe testing, the processor circuit 110 may execute the test code P2 in the code P1 to generate the test signal S2 and transmit the test signal S2 to the circuit 170 via the bus circuit 130. Thus, in response to the test signal S2, the circuit 170 may perform corresponding circuit behaviors and accordingly return the test results to the processor circuit 110 and/or external tools (not shown) to determine whether a transition delay fault exists within the circuit 170 and identify the location of the node that causes the transition delay fault.

The clock generator circuit 180 is configured to generate the clock signal CK0 and transmit the clock signal CK0 to the processor circuit 110. Thus, the processor circuit 110 may operate according to the clock signal CK0. The clock generator circuit 182 is configured to generate the clock signal CK1 and transmit the clock signal CK1 to the circuit 140 and the asynchronous circuit 150, such that these two circuits may operate according to the clock signal CK1. Similarly, the clock generator circuit 184 is configured to generate the clock signal CK2 and transmit the clock signal CK2 to the circuit 160 and the asynchronous circuit 150, such that these two circuits may operate according to the clock signal CK2. In some embodiments, during chip probe testing, the clock generator circuits 180, 182, and 184 may be enabled via external tools (or controlled by the processor circuit 110) to generate the clock signals CK0, CK1, and CK2 that are, for example, at full speed. In other words, each of the clock signals CK0, CK1, and CK2 during the chip probe testing are full-speed clock signals (rather than downscaled clock signals). In some embodiments, the frequency of each of the full-speed clock signals CK0, CK1, and CK2 are the predetermined frequencies for the chip 100 (and/or the processor circuit 110) when operating in the normal mode. Thus, during the chip probe testing, the processor circuit 110, the circuit 140, the asynchronous circuit 150, and the circuit 160 may perform the aforementioned transition delay fault test according to the full-speed clock signals CK0, CK1, and CK2. As a result, it is able to test the circuits under test without using low-speed clock signals provided by external tools, and thus the accuracy of circuit test can be improved.

In some embodiments, each of the clock generator circuits 180, 182, and 184 may be, but not limited to, a phase-locked loop circuit. In some embodiments, the chip 100 further includes another clock generator circuit (not shown) that provides the clock signal required for the circuit 170. In some embodiments, at least two of the aforementioned clock generator circuits may be integrated into the same circuit or share part of the circuit. In other words, the configuration of the clock generator circuits is not limited to the configuration shown in FIG. 1.

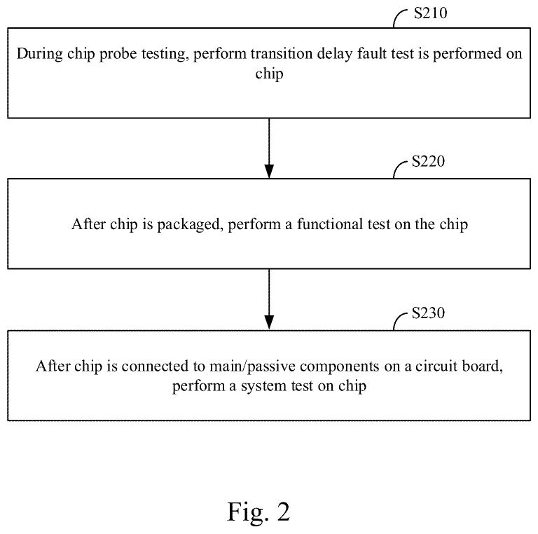

FIG. 2 illustrates a flowchart of a multi-stage test performed on the chip 100 according to some embodiments of the present disclosure. In operation S210, a transition delay fault test is performed on a chip during a chip probe testing. In some embodiments, the chip probe testing is performed before the chip 100 is packaged. In other words, the chip probe testing is a wafer-level test. In general, during the chip probe testing, an external tool may connect with the chip 100 (which may be a die on a wafer at this stage) via a probe card, in order to drive the processor circuit 110 to execute the code P1 to perform the aforementioned transition delay fault test. In some embodiments, during the chip probe testing, the chip 100 may also be configured to perform a scan test.

In operation S220, after the chip is packaged, a functional test is performed on the chip. Different from the chip probe testing, the test executed in operation S220 is a circuit test performed on the chip 100 after the chip 100 is packaged to determine whether there is a defect in the packaged chip 100. That is, the functional test is a chip-level test. In operation S230, after the chip is connected to the main/passive components on a circuit board, a system test is performed on the chip. Different from the previous two tests, the test executed in operation S230 is a system test performed after the packaged chip 100 is installed on the circuit board and connected to different main/passive components to determine whether there is a defect in the overall system. In other words, the system test is a system-level test.

In some related approaches, due to actual tool limitations, only slower clock signals (not full-speed) may be employed for test during the chip probe testing, and only circuits in a single clock domain may be tested for transition delay faults. For example, in these approaches, only the circuit 140 operating in the first clock domain and/or the circuit 160 operating in the second clock domain may be tested for transition delay faults, and the asynchronous circuit 150 cannot be tested. In these approaches, additional test patterns are required to be input through external tools in the next stage of functional test to test asynchronous circuits (such as the asynchronous circuit 150) for transition delay faults.

It is understood that in actual applications, the later the test stage, the higher the cost. If the faults or defects of the chip 100 can be found in the earlier test stage, the more overall manufacturing cost can be saved. Different from the aforementioned related approaches, in some embodiments of the present disclosure, during the chip probe testing, the processor circuit 110 in the chip 100 may execute the code P1, which are able to be executed in a normal mode, to test the asynchronous circuit 150 (or any other circuit) for transition delay faults, where the processor circuit 110 and other circuits under test in the chip 100 operate according to the full-speed clock signals (e.g., the clock signals CK0 to CK2) that are generated from the chip 100 itself. Thus, a more reliable transition delay fault test can be performed during the chip probe testing. Compared with the aforementioned related approaches, it is able to determine whether there is a transition delay fault in the chip 100 earlier during the chip probe testing stage, in order to revise the chip 100 more timely and save more manufacturing costs.

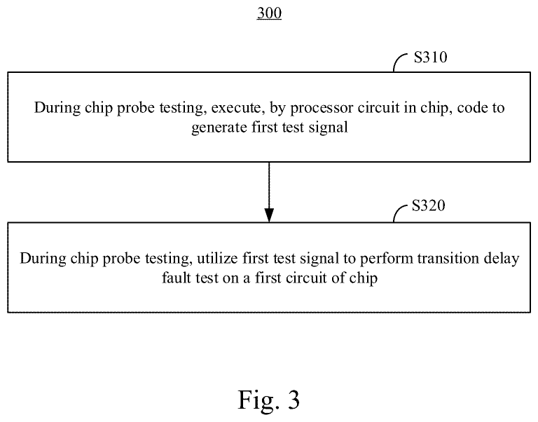

FIG. 3 illustrates a flowchart of a chip testing method 300 according to some embodiments of the present disclosure. In some embodiments, the chip testing method 300 may be executed by, but is not limited to, the processor circuit 110 in FIG. 1 in cooperation with an external tool.

In operation S310, during a chip probe testing, a processor circuit in a chip executes a code to generate a first test signal. In operation S320, during the chip probe testing, the first test signal is utilized to perform a transition delay fault test on a first circuit in the chip.

For example, during the chip probe testing, the processor circuit 110 may execute the code P1 stored in the memory circuit 120 to generate the test signal S1, such that the circuit 140 (and/or the circuit 160) may generate corresponding output in response to the test signal S1, such that it is able to determine whether the circuit 140 (and/or the circuit 160) has a transition delay fault based on this output. On the other hand, during the chip probe testing, the processor circuit 110 may also generate the test signal S1, such that one of the circuits 140 and 160 may access the other via the asynchronous circuit 150 in response to the test signal S1, such that it is able to determine whether the asynchronous circuit 150 has a transition delay fault based on the signals at internal nodes of the asynchronous circuit 150. Alternatively, during the chip probe testing, the processor circuit 110 may execute the test code P2 in the code P1 to generate the test signal S2, such that the circuit 170, which is independent of the aforementioned other circuits (e.g., the circuit 140, the asynchronous circuit 150, and/or the circuit 160), may generate corresponding output in response to the test signal S2, and thus it is able to determine whether the circuit 170 has a transition delay fault based on this output.

Operations of the chip testing method 300 can be understood with reference to the above embodiments, and thus the repetitious descriptions are not further given. The above operations of the chip testing method 300 include exemplary operations, but those operations are not necessarily performed in the order described above. Operations of the chip testing method 300 may be added, replaced, changed order, and/or eliminated, or the operations of the chip testing method 300 may be performed simultaneously or partially simultaneously as appropriate, in accordance with the spirit and scope of various embodiments of the present disclosure. In some embodiments, the chip testing method 300 may further include the following operations: during the chip probe testing, a clock generator circuit is enabled to generate a clock signal (for example, at full speed). For example, during the chip probe testing, the clock generator circuits 180, 182, and 184 may be enabled to generate the full-speed clock signals CK0, CK1, and CK2, such that the processor circuit 110 and other circuits under test may operate according to these clock signals CK0, CK1, and CK2, thereby obtaining test results that match actual application environments.

As described above, the chip and chip testing method provided in some embodiments of the present disclosure may utilize, during a chip probe testing stage, full-speed clock signals to perform a transition delay fault test on a chip before packaging, in order to obtain effective test results and effectively reducing overall costs.

Various functional components or blocks have been described herein. As will be appreciated by persons skilled in the art, in some embodiments, the functional blocks will preferably be implemented through circuits (either dedicated circuits, or general purpose circuits, which operate under the control of one or more processors and coded instructions), which will typically comprise transistors or other circuit elements that are configured in such a way as to control the operation of the circuitry in accordance with the functions and operations described herein. As will be further appreciated, the specific structure or interconnections of the circuit elements will typically be determined by a compiler, such as a register transfer language (RTL) compiler. RTL compilers operate upon scripts that closely resemble assembly language code, to compile the script into a form that is used for the layout or fabrication of the ultimate circuitry. Indeed, RTL is well known for its role and use in the facilitation of the design process of electronic and digital systems.

The aforementioned descriptions represent merely the preferred embodiments of the present disclosure, without any intention to limit the scope of the present disclosure thereto. Various equivalent changes, alterations, or modifications based on the claims of the present disclosure are all consequently viewed as being embraced by the scope of the present disclosure.

What is claimed is:

1. A chip testing method, comprising:
during a chip probe testing, executing, by a processor circuit in a chip, a code to generate a first test signal; and
during the chip probe testing, utilizing the first test signal to perform a transition delay fault test on a first circuit in the chip.

2. The chip testing method of claim 1, further comprising:
during the chip probe testing, utilizing the first test signal to perform the transition delay fault test on an asynchronous circuit in the chip,
wherein the asynchronous circuit is coupled between the first circuit and a second circuit in the chip, and the first circuit is configured to access the second circuit via the asynchronous circuit in response to the first test signal.

3. The chip testing method of claim 2, wherein the first circuit is configured to operate according to a first clock signal, the second circuit is configured to operate according to a second clock signal, the asynchronous circuit is configured to operate according to the first clock signal and the second clock signal, and the first clock signal and the second clock signal are asynchronous.

4. The chip testing method of claim 3, wherein the first clock signal and the second clock signal come from different clock sources, or a frequency of one of the first clock signal and the second clock signal is not an integer of a frequency of another one of the first clock signal and the second clock signal.

5. The chip testing method of claim 2, further comprising:
during the chip probe testing, enabling a first clock generator circuit to generate a first clock signal and transmit the first clock signal to the first circuit and the asynchronous circuit;
during the chip probe testing, enabling a second clock generator circuit to generate a second clock signal and transmit the second clock signal to the second circuit and the asynchronous circuit; and
during the chip probe testing, enabling a third clock generator circuit to generate a third clock signal and transmit the third clock signal to the processor circuit.

6. The chip testing method of claim 5, wherein each of the first clock signal, the second clock signal, and the third clock signal is a full-speed clock signal during the chip probe testing.

7. The chip testing method of claim 1, wherein the code comprises a program code executed by the processor circuit during a boot process.

8. The chip testing method of claim 1, wherein the code is stored in a read-only memory circuit in the chip.

9. The chip testing method of claim 1, further comprising:
during the chip probe testing, executing, by the processor circuit, a test code in the code to generate a second test signal; and
during the chip probe testing, utilizing the second test signal to perform the transition delay fault test on a second circuit in the chip,
wherein one of the first circuit and the second circuit does not access another one of the first circuit and the second circuit.

10. The chip testing method of claim 9, wherein the second circuit comprises a static random-access memory circuit.

11. A chip, comprising:
a memory circuit configured to store a code;
a processor circuit configured to execute the code during a chip probe testing to generate a first test signal; and
a first circuit coupled to the processor circuit via a bus circuit and configured to perform a transition delay fault test in response to the first test signal during the chip probe testing.

12. The chip of claim 11, further comprising:
a second circuit; and
an asynchronous circuit coupled between the first circuit and the second circuit,
wherein the processor circuit is further configured to utilize the first test signal to perform the transition delay fault test on the asynchronous circuit during the chip probe testing, and the first circuit is further configured to access the second circuit via the asynchronous circuit in response to the first test signal.

13. The chip of claim 12, wherein the first circuit is configured to operate according to a first clock signal, the second circuit is configured to operate according to a second clock signal, the asynchronous circuit is configured to operate according to the first clock signal and the second clock signal, and the first clock signal and the second clock signal are asynchronous.

14. The chip of claim 13, wherein the first clock signal and the second clock signal come from different clock sources, or a frequency of one of the first clock signal and the second clock signal is not an integer of a frequency of another one of the first clock signal and the second clock signal.

15. The chip of claim 12, further comprising:
a first clock generator circuit configured to generate a first clock signal during the chip probe testing and transmit the first clock signal to the first circuit and the asynchronous circuit;
a second clock generator circuit configured to generate a second clock signal during the chip probe testing and transmit the second clock signal to the second circuit and the asynchronous circuit; and
a third clock generator circuit configured to generate a third clock signal during the chip probe testing and transmit the third clock signal to the processor circuit.

16. The chip of claim 15, wherein each of the first clock signal, the second clock signal, and the third clock signal is a full-speed clock signal during the chip probe testing.

17. The chip of claim 11, wherein the code comprises a program code executed by the processor circuit during a boot process.

18. The chip of claim 11, wherein the memory circuit is a read-only memory circuit.

19. The chip of claim 11, further comprising:
a second circuit configured to perform the transition delay fault test in response to a second test signal during the chip probe testing,
wherein the processor circuit is further configured to execute a test code in the code to generate the second test signal during the chip probe testing, and one of the first circuit and the second circuit does not access another one of the first circuit and the second circuit.

20. The chip of claim 19, wherein the second circuit comprises a static random-access memory circuit.
